(19) United States
(12) Patent Application Publication
(10) Pub. No.: US 2014/0326944 A1
(43) Pub. Date: Nov. 6, 2014

(54) NITRIDE SEMICONDUCTOR LIGHT EMITTING DEVICE AND METHOD OF MANUFACTURING THE SAME

(71) Applicant: SAMSUNG ELECTRONICS CO., LTD., Suwon-si (KR)

(72) Inventors: Hyun Wook SHIM, Suwon-si (KR); Jin Young LIM, Gwacheon-si (KR); Jae Sung HYUN, Hwaseong-si (KR)

(73) Assignee: SAMSUNG ELECTRONICS CO., LTD., Suwon-si (KR)

(21) Appl. No.: 14/192,776

(22) Filed: Feb. 27, 2014

(30) Foreign Application Priority Data
May 6, 2013 (KR) 10-2013-0050587

(51) Int. Cl. H01L 33/06; H01L 33/26

(52) U.S. Cl. CPC H01L 33/06; H01L 33/26
USPC 257/13; 438/47

(57) ABSTRACT

A method of manufacturing a nitride semiconductor light emitting device includes forming a first conductivity type nitride semiconductor layer. An active layer is formed on the first conductivity type nitride semiconductor layer. A second conductivity type nitride semiconductor layer is formed on the active layer. In the forming of the active layer, quantum well layers and quantum barrier layers are alternatively stacked and at least two dopant layers are formed inside of at least one of the quantum well layers. The dopant layers are doped with a dopant in a predetermined concentration.

### CROSS-REFERENCE TO RELATED APPLICATION

This application claims benefit of priority to Korean Patent Application No. 10-2013-0050587 filed on May 6, 2013, with the Korean Intellectual Property Office, the entire contents of which are hereby incorporated by reference.

### TECHNICAL FIELD

The present disclosure relates to a nitride semiconductor light emitting device and a method of manufacturing the same.

### BACKGROUND

A light emitting diode (LED) is a device emitting light through a material contained therein when power is applied thereto. LEDs convert energy generated through electron-hole recombination occurring at p-n junctions between p-type and n-type semiconductors into light to be emitted therefrom. Such LEDs have been widely used as light sources in lighting devices, display devices, and the like, and the development thereof is therefore being accelerated.

In particular, as mobile phone keypads, side viewers, camera flashes and the like using LEDs (e.g., GaN-based LEDs) are commercialized, the development of general lighting devices using LEDs is being actively undertaken. As the use of LEDs is extended from small portable devices to large, high output, and high efficiency products, such as the backlight units of large screen TVs, the headlights of vehicles, general lighting devices, and the like, a method of improving light extraction efficiency of light emitting devices for use in the corresponding products has been demanded.

### SUMMARY

An aspect of the present disclosure provides a nitride semiconductor light emitting device having improved light extraction efficiency.

An aspect of the present disclosure relates to a method of manufacturing a nitride semiconductor light emitting device. The method includes forming a first conductivity type nitride semiconductor layer, forming an active layer on the first conductivity type nitride semiconductor layer, and forming a second conductivity type nitride semiconductor layer on the active layer. The forming of the active layer includes alternately stacking quantum well layers and quantum barrier layers and forming at least two dopant layers inside at least one of the quantum well layers by being doped with a dopant in a predetermined concentration.

The dopant may be selected from the group consisting of Si, Mg and Zn.

The dopant may be added in a concentration of 5×10¹⁶/cm³ to 5×10¹⁷/cm³.

The at least two dopant layers may be spaced apart from one another.

The at least two dopant layers may be spaced apart from one another by an interval of 2 nm to 2.5 nm.

Each quantum well layer may include five to ten monolayers.

The at least two dopant layers may be spaced apart from interfaces between a quantum well layer and adjacent quantum barrier layers by an interval of at least one monolayer.

The at least two dopant layers may be spaced apart from interfaces between a quantum well layer and adjacent quantum barrier layers by an interval of at least 0.5 nm.

The quantum well layers and the quantum barrier layers may be formed of InₓAl_{y}Ga_{(1-x-y)}N (0≦x≦1, 0≦y≦1, 0≦x+y≦1).

The quantum well layers may be formed of InₓGa₍₁₋ₓ₎N (0<x<1), and the quantum barrier layers may be formed of In_{y}Ga_{(1-y)}N (0≦y<x).

Another aspect of the present disclosure encompasses a nitride semiconductor light emitting device, including a first conductivity type nitride semiconductor layer, an active layer disposed on the first conductivity type nitride semiconductor layer and including quantum well layers and quantum barrier layers alternately stacked and at least two dopant layers disposed inside at least one of the quantum well layers by being doped with a dopant in a predetermined concentration, and a second conductivity type nitride semiconductor layer disposed on the active layer.

The dopant may be selected from the group consisting of Si, Mg and Zn.

The at least two dopant layers may be spaced apart from one another.

The at least two dopant layers may be spaced apart from interfaces between a quantum well layer and adjacent quantum barrier layers by an interval of at least one monolayer.

The at least two dopant layers may be spaced apart from interfaces between a quantum well layer and adjacent quantum barrier layers by an interval of at least 0.5 nm.

Still another aspect of the present disclosure relates to a nitride semiconductor light emitting device package. The package includes a package body, a pair of lead frames disposed on the package body, a nitride semiconductor light emitting device disposed on the pair of lead frames to be electrically connected thereto using a wire. The nitride semiconductor light emitting device includes a first conductivity type nitride semiconductor layer, an active layer disposed on the first conductivity type nitride semiconductor layer and including quantum well layers and quantum barrier layers alternately stacked. At least two dopant layers are disposed inside of at least one of the quantum well layers and doped with a dopant in a predetermined concentration. A second conductivity type nitride semiconductor layer disposed on the active layer.

The dopant may be selected from the group consisting of Si, Mg and Zn.

The at least two dopant layers may be spaced apart from each other.

The at least two dopant layers may be spaced apart from interfaces between a quantum well layer and adjacent quantum barrier layers by an interval of at least one monolayer.

The at least two dopant layers may be spaced apart from interfaces between a quantum well layer and adjacent quantum barrier layers by an interval of at least 0.5 nm.

### BRIEF DESCRIPTION OF THE DRAWINGS

The above and other aspects, features and other advantages of the present disclosure will be more clearly understood from the following detailed description taken in conjunction with the accompanying drawings, in which like reference characters may refer to the same or similar parts throughout the different views. The drawings are not necessarily to scale, emphasis instead being placed upon illustrating the principles of the embodiments of the present disclosure. In the drawings, the thickness of layers and regions may be exaggerated for clarity.

FIG. 1 is a cross-sectional view of a nitride semiconductor light emitting device according to an embodiment of the present disclosure.

FIG. 2 is an enlarged view of part A of FIG. 1.

FIG. 3 is an enlarged view of a quantum well layer of FIG. 2.

FIG. 4 is a graph illustrating an amount of dopants added to the quantum well layer during the growth thereof.

FIGS. 5 through 8 are cross-sectional views illustrating a method of manufacturing the nitride semiconductor light emitting device of FIG. 1.

FIG. 9 is a cross-sectional view schematically illustrating a state in which a nitride semiconductor light emitting device according to an embodiment of the present disclosure is mounted in a package.

FIG. 10 is a cross-sectional view schematically illustrating an example of a backlight including the package of FIG. 9.

FIG. 11 is a cross-sectional view schematically illustrating another example of a backlight including the package of FIG. 9.

FIG. 12 illustrates an example of applying a nitride semiconductor light emitting device according to an embodiment of the present disclosure to a lighting device.

FIG. 13 illustrates an example of applying a nitride semiconductor light emitting device according to an embodiment of the present disclosure to a headlamp.

### DETAILED DESCRIPTION

Embodiments of the present disclosure will now be described in detail with reference to the accompanying drawings.

The present inventive concept may, however, be exemplified in many different forms and should not be construed as being limited to the specific embodiments set forth herein. Rather, these embodiments are provided so that this disclosure will be thorough and complete, and will fully convey the scope of the inventive concept to those skilled in the art.

In the drawings, the shapes and dimensions of elements may be exaggerated for clarity, and the same reference numerals will be used throughout to designate the same or like elements.

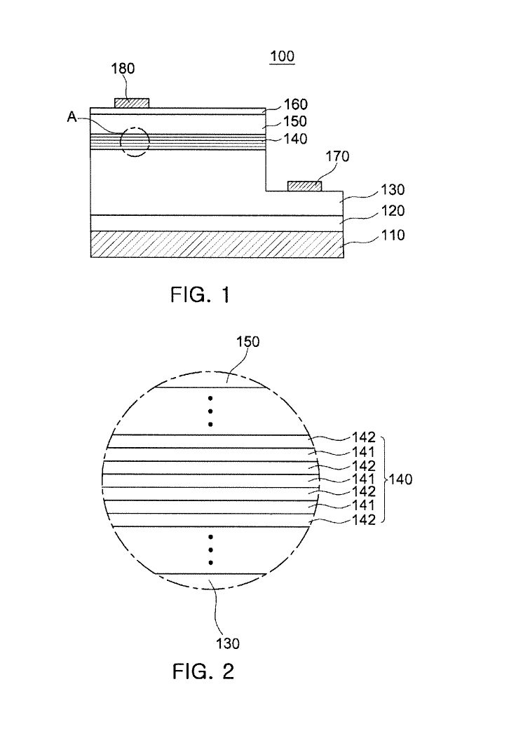

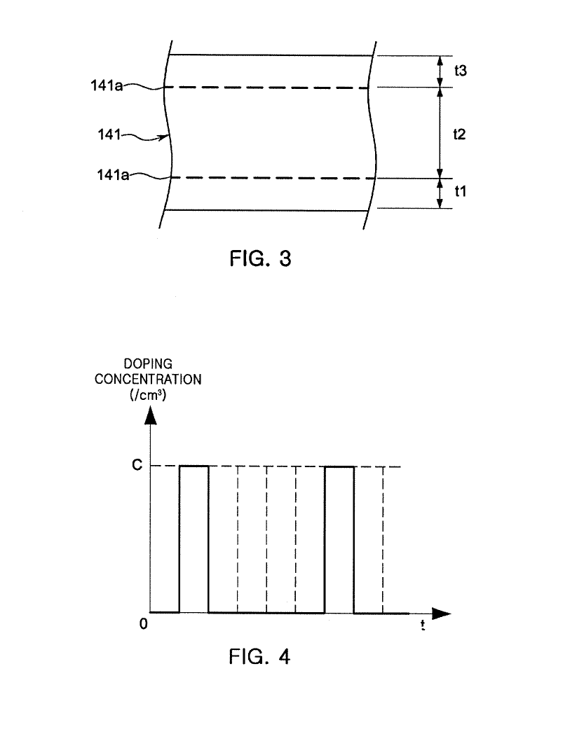

FIG. 1 is a cross-sectional view of a nitride semiconductor light emitting device according to an embodiment of the present disclosure, and FIG. 2 is an enlarged view of part A of FIG. 1. FIG. 3 is an enlarged view of a quantum well layer of FIG. 2, and FIG. 4 is a graph illustrating an amount of dopants added to the quantum well layer during the growth thereof.

A nitride semiconductor light emitting device 100 may include a first conductivity type nitride semiconductor layer 130, an active layer 140 and a second conductivity type nitride semiconductor layer 150.

The first conductivity type nitride semiconductor layer 130, the active layer 140 and the second conductivity type nitride semiconductor layer 150 may constitute a light emitting structure. When power is applied to the first and second conductivity type nitride semiconductor layers 130 and 150, light is emitted from the active layer 140.

Specifically, the first conductivity type nitride semiconductor layer 130 may include an n-type semiconductor layer, and the second conductivity type nitride semiconductor layer 150 may include a p-type semiconductor layer. The n-type and p-type semiconductor layers may be formed of semiconductor materials having a composition formula of InₓAl_{y}Ga_{(1-x-y)}N and doped with n-type and p-type dopants, and representative materials thereof may include GaN, AlGaN, and InGaN. Here, x and y values may have the following ranges: 0≦x≦1, 0≦y≦1, and 0≦x+y≦1.

As the n-type dopant, Si, Ge, Se, Te, C or the like may be used. As the p-type dopant, Mg, Zn, Be or the like may be used.

In an exemplary embodiment of the present disclosure, a GaN layer may be used as the first and second conductivity type nitride semiconductor layers 130 and 150. That is, an n-GaN layer may be used as the first conductivity type nitride semiconductor layer 130, and a p-GaN layer may be used as the second conductivity type nitride semiconductor layer 150.

The first and second conductivity type nitride semiconductor layers 130 and 150 and the active layer 140 may be grown on a substrate 110 by metal organic chemical vapor deposition (MOCVD), molecular beam epitaxy (MBE), hydride vapor phase epitaxy (HVPE) or the like. The substrate 110 may be formed of sapphire (Al₂O₃), SiC, Si, MgAl₂O₄, MgO, LiAlO₂, LiGaO₂ or GaN, but is not limited thereto. In an exemplary embodiment of the present disclosure, a sapphire substrate may be used.

Sapphire is a crystal having Hexa-Rhombo R3C symmetry, and has a lattice constant of 13.001 Å along a C-axis and a lattice constant of 4.758 Å along an A-axis. Orientation planes of the sapphire include a C (0001) plane, an A (1120) plane, an R (1102) plane, and the like. Particularly, the C plane is mainly used as a substrate for nitride growth because it relatively facilitates the growth of a nitride film and is stable at high temperatures.

In addition, a buffer layer 120 may be formed below the first conductivity type nitride semiconductor layer 130.

The buffer layer 120 may be provided to alleviate lattice defects in the first conductivity type nitride semiconductor layer 130 to be grown on the substrate 110, and may be provided as an undoped semiconductor layer formed of nitride or the like. For example, a difference in lattice constants between a sapphire substrate and GaN semiconductor layers stacked on a top surface of the sapphire substrate may be alleviated to thereby increase the crystallinity of the GaN semiconductor layers. The buffer layer 120 may be formed of an undoped GaN layer, an undoped AlN layer, an undoped InGaN layer, or the like, and may be grown to have a thickness of tens to hundreds of Å at a relatively low temperature of 500° C. to 600° C. In this case, the “undoped” semiconductor layer refers to a semiconductor layer that is not intentionally doped with any dopant, but there may be portions of a dopant inevitably included therein. For example, when a GaN semiconductor layer is grown by metal organic chemical vapor deposition (MOCVD), a concentration of a dopant, such as Si or the like, inevitably present in the semiconductor layer, may be within a range of approximately 10¹⁴/cm³ to 10¹⁸/cm³.

The active layer 140 may be a light emitting layer for emitting visible light having a wavelength of approximately 350 nm to 680 nm. As shown in FIG. 2, the active layer 140 may be formed of nitride semiconductor layers having a multi-quantum-well (MQW) structure. The active layer 140 may have a multi-quantum-well structure in which quantum well layers 141 and quantum barrier layers 142 are alternately stacked. Specifically, the active layer 140 may have the multi-quantum-well structure in which the quantum well layers 141 formed of InₓGa₍₁₋ₓ₎N (0<x<1) and the quantum barrier layers 142 formed of In_{y}Ga_{(1-y)}N (0≦y<x) are alternately stacked. Therefore, the active layer 140 may have a predetermined energy bandgap and emit light through recombination of electrons and holes in quantum wells.

However, the active layer 140 may be damaged during the manufacturing of the nitride semiconductor light emitting device 100. Therefore, when light emitting efficiency of active layers is measured within a chip structure, the light emitting efficiency may be decreased as compared with when light emitting efficiency is measured after only active layers are grown.

For example, when quantum well layers are formed of InGaN, In of InGaN may be diffused by heat. Therefore, when excessive heat is applied to the quantum well layers during the forming of the quantum well layers in the chip structure, In may be diffused to damage the quantum well layers.

In general, an active layer is grown at approximately 800° C. and a second conductivity type nitride semiconductor layer is grown at approximately 1000° C., and thus In of InGaN may be diffused. In the chip manufacturing process, an ohmic heating process may also accelerate the diffusion of In.

Therefore, the multi-quantum-well structure of the active layer may be deteriorated through the nitride semiconductor layer growth process or the heating process in the chip manufacturing process. In order to alleviate the deterioration of the active layer, the active layer may be doped with a dopant such as Si during the growth thereof. However, when the entirety of the quantum well layers and the quantum barrier layers included in the active layer is doped with dopants, leakage current may increase or quantum efficiency droop may occur. Thus, failing to recombine with holes as an amount of current is increasingly introduced, electrons may easily overflow into the p-type nitride semiconductor layer. Therefore, this leads to a need to prevent leakage current and quantum efficiency droop even when the doping process is performed.

When the quantum well layers are formed of InGaN, InGaN particles may gather together to form small quantum-dot-like clusters. In this case, when the quantum well layers take on quantum-dot-like properties, quantum efficiency may be improved. However, as InGaN clusters are gradually increased in size, they may lose the quantum-dot-like properties, resulting in a reduction in quantum efficiency. Therefore, the InGaN clusters need to remain as relatively small clusters in order to maintain the quantum-dot-like properties.

Referring to FIG. 3, in the nitride semiconductor light emitting device 100 according to an embodiment of the present disclosure, dopant layers 141a may be formed inside the quantum well layer 141 to block heat from being transferred toward the entirety of the quantum well layer 141, thereby preventing the deterioration of the quantum well layer 141. Since the dopant layers 141a are formed inside of the quantum well layer 141, they may prevent the occurrence of the leakage current and the efficiency droop that may result from the doping of the entirety of the active layer. In addition, the quantum well layer 141 may be maintained as a plurality of small clusters by preventing the small clusters from aggregating together and increasing in size.

With reference to FIG. 3, the quantum well layer 141 may include five to ten monolayers and have a thickness of t1+t2+t3. The quantum well layer 141 may include at least two dopant layers 141a. Here, the at least two dopant layers 141a may be spaced apart from one another. The at least two dopant layers 141a may be included in at least one quantum well layer among the plurality of quantum well layers 141, and may be disposed inside of the at least one quantum well layer, rather than at interfaces between the quantum well layer 141 and the quantum barrier layers 142 adjacent thereto. The at least two dopant layers 141a may be spaced apart from the interfaces by an interval of at least one monolayer.

The dopant for the doping of the dopant layers 141a may be at least one selected from Si, Mg and Zn. The quantum well layer 141 may be doped with the selected dopant in a concentration of 5×10¹⁶/cm³ to 5×10¹⁷/cm³.

Specifically, the quantum well layer 141 may have a thickness of approximately 3 nm to 3.5 nm (t1+t2+t3), but the thickness of the quantum well layer 141 is not limited thereto. The at least two dopant layers 141a may be disposed to have an interval (t1, t3) of approximately 0.5 nm from upper and lower interfaces between the quantum well layer 141 and the adjacent quantum barrier layers 142. When the at least two dopant layers 141a are disposed inside the quantum well layer 141, they are spaced apart from one another by an interval (t2) of 2 nm to 2.5 nm.

In the nitride semiconductor light emitting device 100, the quantum well layer 141 may include the dopant layers 141a during the growth thereof, such that the quantum well layer 141 may be divided into a plurality of small clusters. Therefore, the dopant layers 141a formed inside the quantum well layer 141 prevent the small clusters from being enlarged, whereby quantum efficiency may be improved. In addition, the improved quantum efficiency may lead to an increase in luminance of the nitride semiconductor light emitting device 100. When the dopant layers 141a are formed inside the quantum well layer 141, an amount of light may be increased by approximately 1%, as compared with an amount of light of a counterpart case.

First and second electrodes 170 and 180 may be formed on the first and second conductivity type nitride semiconductor layers 130 and 150, respectively (see FIG. 1). The first and second electrodes 170 and 180 may be electrically connected to the first and second conductivity type nitride semiconductor layers 130 and 150, respectively, and when power is applied thereto, light may be emitted from the active layer 140.

In addition, the first and second electrodes 170 and 180 may be provided as areas in contact with a conductive wire, a solder bump, or the like, so as to allow external electrical signals to be applied thereto. The first electrode 170 may be formed on a portion of a top surface of the first conductivity type nitride semiconductor layer 130 exposed by removing portions of the active layer 140 and the second conductivity type nitride semiconductor layer 150 from the light emitting structure. The second electrode 180 may be formed on the second conductivity type nitride semiconductor layer 150.

A current diffusion layer 160 may be formed on a top surface of the second conductivity type nitride semiconductor layer 150. The current diffusion layer 160 may be provided to allow current supplied from the second electrode 180 to be diffused to thereby alleviate the concentration of the current only in the area below the second electrode 180. The current diffusion layer 160 may be formed of at least one transparent conductive oxide selected from ITO (Indium Tin Oxide), ZITO (Zinc-doped Indium Tin Oxide), ZIO (Zinc Indium Oxide), GIO (Gallium Indium Oxide), ZTO (Zinc TinOxide), FTO (Fluorine-doped Tin Oxide), AZO (Aluminium-doped Zinc Oxide), GZO (Gallium-doped Zinc Oxide), In₄Sn₃O₁₂ or Zn₍₁₋ₓ₎MgₓO (Zinc Magnesium Oxide, 0≦x≦1).

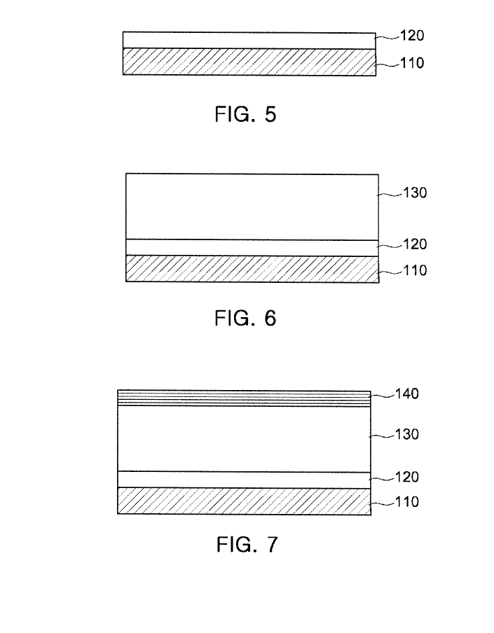

Hereinafter, a method of manufacturing the nitride semiconductor light emitting device 100 according to an exemplary embodiment of the present disclosure will be described with reference to FIGS. 5 through 8. FIGS. 5 through 8 are cross-sectional views illustrating the method of manufacturing the nitride semiconductor light emitting device of FIG. 1.

The method of manufacturing the nitride semiconductor light emitting device 100 according to an exemplary embodiment of the present disclosure may include forming the first conductivity type nitride semiconductor layer 130, forming the active layer 140 on the first conductivity type nitride semiconductor layer 130, and forming the second conductivity type nitride semiconductor layer 150 on the active layer 140.

First, as shown in FIG. 5, the buffer layer 120 may be formed on the substrate 110. As described above, the substrate 110 may be formed of sapphire (Al₂O₃), SiC, Si, MgAl₂O₄, MgO, LiAlO₂, LiGaO₂ or GaN, but is not limited thereto. The buffer layer 120 may not be formed according to embodiments of the present disclosure. The buffer layer 120 may be grown on the substrate 110 by metal organic chemical vapor deposition (MOCVD), molecular beam epitaxy (MBE), hydride vapor phase epitaxy (HYPE) or the like.

Next, as shown in FIG. 6, the first conductivity type nitride semiconductor layer 130 may be formed on the buffer layer 120. The first conductivity type nitride semiconductor layer 130 may be formed of a semiconductor material doped with an n-type dopant and having a composition formula of InₓAl_{y}Ga_{(1-x-y)}N (0≦x≦1, 0≦x≦1, 0≦x+y≦1). In an exemplary embodiment of the present disclosure, the first conductivity type nitride semiconductor layer 130 may be formed of n-GaN.

Then, as shown in FIG. 7, the active layer 140 may be formed on the first conductivity type nitride semiconductor layer 130. The active layer 140 may be grown using a semiconductor material having a composition formula of InₓAl_{y}Ga_{(1-x-y)}N (0≦x≦1, 0≦y≦1, 0≦x+y≦1) by metal organic chemical vapor deposition (MOCVD), molecular beam epitaxy (MBE), hydride vapor phase epitaxy (HYPE) or the like, at a growth temperature of 800° C. to 900° C.

The active layer 140 may be formed by alternately stacking the quantum well layers 141 formed of InₓGa₍₁₋ₓ₎N<x−1) and the quantum barrier layers 142 formed of In_{y}Ga_{(1-y)}N (0≦y<x). Here, the quantum well layers 141 and the quantum barrier layers 142 may be repeatedly stacked 10 to 100 times.

During the growth of the quantum well layer 141, the quantum well layer 141 may be doped with a dopant in a predetermined concentration, so that it may include the dopant layers 141a formed therein (see FIG. 3).

FIG. 4 is a graph illustrating an amount of dopants added at the time of growth of the quantum well layer 141. In the graph, respective dotted lines on a time axis indicate times at which respective monolayers included in the quantum well layer 141 are formed. FIG. 4 illustrates that when second and seventh monolayers, among eight monolayers included in the quantum well layer 141, are formed, they are doped with the dopant. Here, the concentration of the dopant may range from 5×10¹⁶/cm³ to 5×10¹⁷/cm³. When the monolayer is doped with the dopant in a concentration below 5×10¹⁶/cm³, the dopant layer may not be appropriately formed. When the monolayer is doped with the dopant in a concentration above 5×10¹⁷/cm³, the leakage current may be increased to thereby reduce light emitting efficiency.

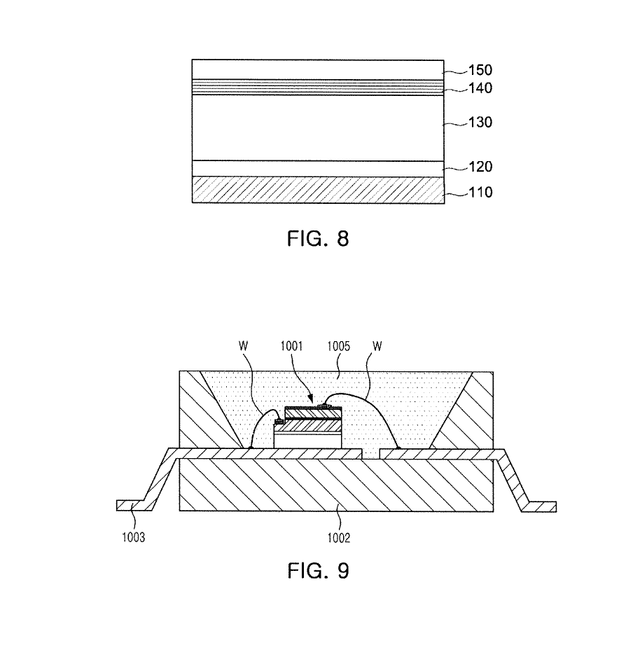

Then, as shown in FIG. 8, the second conductivity type nitride semiconductor layer 150 may be formed on the active layer 140. The second conductivity type nitride semiconductor layer 150 may be formed of a semiconductor material doped with a p-type dopant and having the same composition formula of InₓAl_{y}Ga_{(1-x-y)}N (0≦x≦1, 0≦y≦1, 0≦x+y≦1) as a composition formula of the first conductivity type nitride semiconductor layer 130.

Then, as shown in FIG. 1, the light emitting structure may be mesa-etched to expose a portion of the first conductivity type nitride semiconductor layer 130, and then the first and second electrodes 170 and 180 may be formed on the first and second conductivity type nitride semiconductor layers 130 and 150, respectively. The first and second electrodes 170 and 180 may be formed as a single layer or a multilayer structure using a material selected from Ni, Au, Ag, Ti, Cr or Cu. The first and second electrodes 170 and 180 may be formed by a deposition method such as a chemical vapor deposition (CVD) method and an e-beam evaporation method, a sputtering method or the like.

FIG. 9 illustrates an example of applying a nitride semiconductor light emitting device according to an embodiment of the present disclosure to a package. A package 1000 of FIG. 9 may include a nitride semiconductor light emitting device 1001, a package body 1002, and a pair of lead frames 1003. The nitride semiconductor light emitting device 1001 may be mounted on the pair of lead frames 1003 to be electrically connected thereto using a wire W. The nitride semiconductor light emitting device 1001 may be mounted on another portion of the package 1000 rather than the pair of lead frames 1003, for example, on the package body 1002. The package body 1002 may have a cup shape in order to improve light reflection efficiency, and such a reflective cup may be filled with a light transmissive material 1005 encapsulating the nitride semiconductor light emitting device 1001 and the wire W.

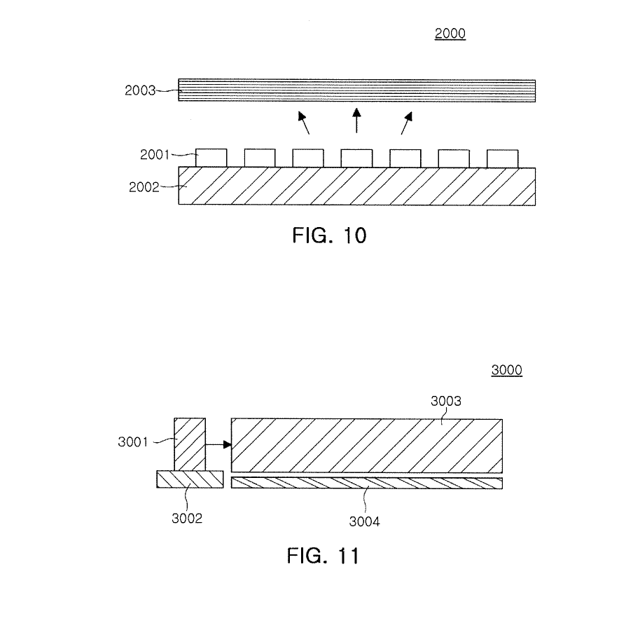

FIGS. 10 and 11 illustrate examples of applying a nitride semiconductor light emitting device according to an embodiment of the present disclosure to backlight units. With reference to FIG. 10, a backlight unit 2000 includes a light source 2001 mounted on a substrate 2002 and at least one optical sheet 2003 disposed thereabove. The light source 2001 may be a nitride semiconductor light emitting device package having the above-described structure of FIG. 9 or a structure similar thereto. Alternatively, a nitride semiconductor light emitting device may be directly mounted on the substrate 2002 in a chip-on-board (COB) scheme. The light source 2001 in the backlight unit 2000 of FIG. 10 emits light toward a liquid crystal display (LCD) device disposed thereabove, whereas a light source 3001 mounted on a substrate 3002 in a backlight unit 3000 of FIG. 11 emits light laterally and the light is incident to a light guide plate 3003 such that the backlight unit 3000 may serve as a surface light source. The light travelling to the light guide plate 3003 may be emitted upwardly and a reflective layer 3004 may be formed under a bottom surface of the light guide plate 3003 in order to improve light extraction efficiency.

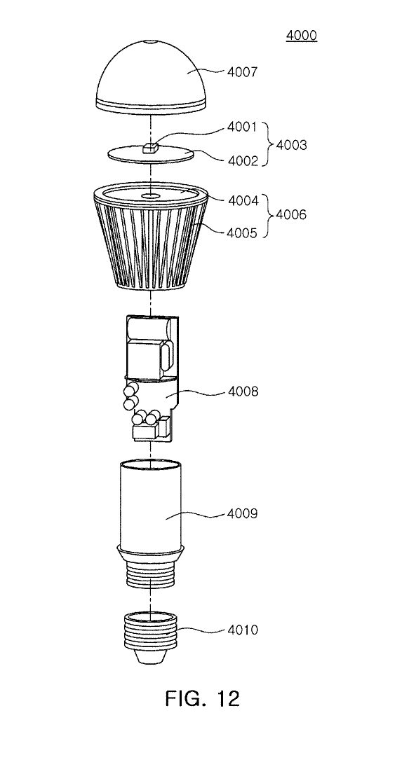

FIG. 12 illustrates an example of applying a nitride semiconductor light emitting device according to an exemplary embodiment of the present disclosure to a lighting device. With reference to an exploded perspective view of FIG. 12, a lighting device 4000 is exemplified as a bulb-type lamp, and includes a light emitting module 4003, a driving unit 4008 and an external connector unit 4010. In addition, exterior structures, such as external and internal housings 4006 and 4009, a cover unit 4007, and the like, may be additionally included. The light emitting module 4003 may include a nitride semiconductor light emitting device 4001 and a circuit board 4002 having the nitride semiconductor light emitting device 4001 mounted thereon. In an exemplary embodiment of the present disclosure, a single nitride semiconductor light emitting device 4001 may be mounted on the circuit board 4002; however, if necessary, a plurality of nitride semiconductor light emitting devices may be mounted thereon. In addition, the nitride semiconductor light emitting device 4001 may be formed as a package and then mounted on the circuit board 4002, rather than being directly mounted thereon.

The external housing 4006 may include a heat sink plate 4004 in direct contact with the light emitting module 4003 to thereby improve heat dissipation, and a heat radiating fin 4005 dissipating heat of the heat sink plate 4004 into air. In addition, the lighting device 4000 may include the cover unit 4007 disposed above the light emitting module 4003 and having a convex lens shape. The driving unit 4008 may be disposed inside the internal housing 4009 and connected to the external connector unit 4010 such as a socket structure to receive power from an external power source. In addition, the driving unit 4008 may convert the received power into power appropriate for driving the nitride semiconductor light emitting device 4001 of the light emitting module 4003 and supply the converted power thereto. For example, the driving unit 4008 may be provided as an AC-DC converter, a rectifying circuit part, or the like.

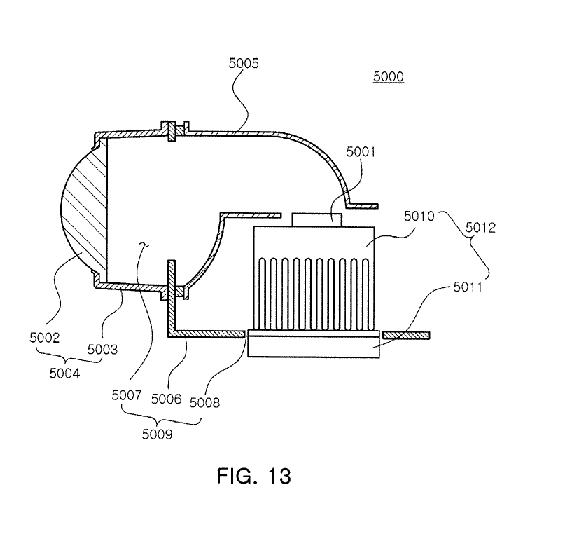

FIG. 13 illustrates an example of applying a nitride semiconductor light emitting device according to an exemplary embodiment of the present disclosure to a headlamp. With reference to FIG. 13, a headlamp 5000 used in a vehicle or the like may include a light source 5001, a reflective unit 5005 and a lens cover unit 5004, the lens cover unit 5004 including a hollow guide part 5003 and a lens 5002. The headlamp 5000 may further include a heat radiating unit 5012 dissipating heat generated in the light source 5001 outwardly. The heat radiating unit 5012 may include a heat sink 5010 and a cooling fan 5011 in order to effectively dissipate heat. In addition, the headlamp 5000 may further include a housing 5009 allowing the heat radiating unit 5012 and the reflective unit 5005 to be fixed thereto and supporting them. One surface 5006 of the housing 5009 may be provided with a central hole 5008 into which the heat radiating unit 5012 is inserted to be coupled thereto. The other surface of the housing 5009 bent in a direction perpendicular to one surface of the housing 5009 may be provided with a forwardly open hole 5007 such that light generated in the light source 5001 may be reflected by the reflective unit 5005 disposed above the light source 5001, pass through the forwardly open hole 5007, and be emitted outwardly.

As set forth above, in a nitride semiconductor light emitting device according to exemplary embodiments of the present disclosure, light extraction efficiency can be improved.

While the present inventive concept has been shown and described in connection with the embodiments of the present disclosure, it will be apparent to those skilled in the art that modifications and variations can be made without departing from the spirit and scope of the inventive concept as defined by the appended claims.

What is claimed is:

1. A method of manufacturing a nitride semiconductor light emitting device, the method comprising:
forming a first conductivity type nitride semiconductor layer;
forming an active layer on the first conductivity type nitride semiconductor layer; and
forming a second conductivity type nitride semiconductor layer on the active layer,
wherein the forming of the active layer includes alternately stacking quantum well layers and quantum barrier layers and forming at least two dopant layers inside of at least one of the quantum well layers, the at least two dopant layers being doped with a dopant in a predetermined concentration.

2. The method of claim 1, wherein the dopant is selected from the group consisting of Si, Mg and Zn.

3. The method of claim 2, wherein the dopant is added in a concentration of 5×10¹⁶/cm³ to 5×10¹⁷/cm³.

4. The method of claim 1, wherein the at least two dopant layers are spaced apart from each other.

5. The method of claim 4, wherein the at least two dopant layers are spaced apart from each other by an interval of 2 nm to 2.5 nm.

6. The method of claim 1, wherein each quantum well layer includes five to ten monolayers.

7. The method of claim 6, wherein the at least two dopant layers are spaced apart from interfaces between a quantum well layer and adjacent quantum barrier layers by an interval of at least one monolayer.

8. The method of claim 1, wherein the at least two dopant layers are spaced apart from interfaces between a quantum well layer and adjacent quantum barrier layers by an interval of at least 0.5 nm.

9. The method of claim 1, wherein the quantum well layers and the quantum barrier layers are formed of InₓAl_{y}Ga_{(1-x-y)}N (0≦x≦1, 0≦y≦1, 0≦x+y≦1).

10. The method of claim 9, wherein the quantum well layers are formed of InₓGa₍₁₋ₓ₎N (0<x<1), and
the quantum barrier layers are formed of In_{y}Ga_{(1-y)}N (0≦y<x).

11. A nitride semiconductor light emitting device, comprising:
a first conductivity type nitride semiconductor layer;
an active layer disposed on the first conductivity type nitride semiconductor layer and including quantum well layers and quantum barrier layers alternately stacked, wherein at least two dopant layers are disposed inside of at least one of the quantum well layers and doped with a dopant in a predetermined concentration; and
a second conductivity type nitride semiconductor layer disposed on the active layer.

12. The nitride semiconductor light emitting device of claim 11, wherein the dopant is selected from the group consisting of Si, Mg and Zn.

13. The nitride semiconductor light emitting device of claim 11, wherein the at least two dopant layers are spaced apart from each other.

14. The nitride semiconductor light emitting device of claim 11, wherein the at least two dopant layers are spaced apart from interfaces between a quantum well layer and adjacent quantum barrier layers by an interval of at least one monolayer.

15. The nitride semiconductor light emitting device of claim 11, wherein the at least two dopant layers are spaced apart from interfaces between a quantum well layer and adjacent quantum barrier layers by an interval of at least 0.5 nm.

16. A nitride semiconductor light emitting device package, comprising:
a package body;
a pair of lead frames disposed on the package body;
a nitride semiconductor light emitting device disposed on the pair of lead frames to be electrically connected thereto using a wire,
wherein the nitride semiconductor light emitting device includes:
a first conductivity type nitride semiconductor layer;
an active layer disposed on the first conductivity type nitride semiconductor layer and including quantum well layers and quantum barrier layers alternately stacked, wherein at least two dopant layers are disposed inside of at least one of the quantum well layers and doped with a dopant in a predetermined concentration; and
a second conductivity type nitride semiconductor layer disposed on the active layer.

17. The nitride semiconductor light emitting device package of claim 16, wherein the dopant is selected from the group consisting of Si, Mg and Zn.

18. The nitride semiconductor light emitting device package of claim 16, wherein the at least two dopant layers are spaced apart from each other.

19. The nitride semiconductor light emitting device package of claim 16, wherein the at least two dopant layers are spaced apart from interfaces between a quantum well layer and adjacent quantum barrier layers by an interval of at least one monolayer.

20. The nitride semiconductor light emitting device package of claim 16, wherein the at least two dopant layers are spaced apart from interfaces between a quantum well layer and adjacent quantum barrier layers by an interval of at least 0.5 nm.
